(19) United States
(12) Patent Application Publication
(10) Pub. No.: US 2006/0148188 A1
(43) Pub. Date: Jul. 6, 2006

(54) Fabrication method for bipolar integrated circuits

(75) Inventors: Xian Feng Liu, Shanghai (CN); Chong Ren, Shanghai (CN); Bin Qiu, Shanghai (CN); Xu Xu, Shanghai (CN)

Correspondence Address: BIRCH STEWART KOLASCH & BIRCH, PO BOX 747, FALLS CHURCH, VA, 22040-0747, US

(73) Assignee: BCD Semiconductor Manufacturing Limited

(21) Appl. No.: 11/028,666

(22) Filed: Jan. 5, 2005

(51) Int. Cl. H01L 21/8222

(52) U.S. Cl. 438/329; 438/353; 438/370

(57) ABSTRACT

A fabrication method is applied to the bipolar integrated circuit, which combines with various patterns of the masks using in the different processes to form a combination mask. By using the combination mask, a silicon dioxide layer is etched to produce the open windows required in the different processes. Thereafter, according to the requirements of different processes, the unused windows are covered with photoresists to avoid the alignment errors resulted from the pattering and etching of different masks. Because the method doesn't need to reserve tolerance for alignment errors, the degree of integration of the semiconductor processes is enhanced and the cost of production is reduced.

### FIELD OF THE INVENTION

The invention presents a fabrication method to enhance the degree of integration for integrated circuits, especially for the fabrication of bipolar integrated circuits.

### BACKGROUND OF THE INVENTION

In the sense of the semiconductor industry, the cost of production depends on the area of epitaxy in the integrated circuit. Therefore, to enhance the degree of integration of integrated circuits and to reduce the area of epitaxy are the objectives for the semiconductor industry.

The bipolar integrated circuit is an important and a basic circuit in the integrated circuits. The conventional processes for bipolar integrated circuit is offer a P-type substrate, N-type buried layer, a N-type epitaxy, a deep N-type sinker, an isolation region, a base, an emitter, a contact metal, and a passivation layer.

In order to reduce the area of isolation, a P-type buried layer can be implanted before the formation of a N-type epitaxy, thereby reducing the width for isolating diffusion. To enhance the performance of the integrated circuit, an extrinsic base can be added beside the base. Moreover, to consider the design flexibility and the performance of the circuit, the integrated circuit can be cooperated with the implanted resistor and capacitor in the process. Conventionally, to fabricate the bipolar integrated circuit needs eight to twelve masks.

Because the fabrication of bipolar integrated circuit needs eight to twelve masks, the alignment errors from different masks exit in the processes, and so that the tolerance must be reserved for the compensation of alignment errors. However, due to this reason the degree of integration of the integrated circuit can't upgrade, and the cost of fabrication can't drop down.

### SUMMARY OF THE INVENTION

Therefore, the purpose of this invention is to present a fabrication method which can reduce the epitaxy area of the integrated circuit and the cost of production, so that the degree of integration is enhanced.

Another objective of the invention is to combine different patterns of masks in one mask, thereby reducing the utalization of mask and the cost of production.

The process sequence of the bipolar integrated circuit in this invention starts with a P-type substrate implanted with a N-type buried layer, surfaced with a N-type epitaxial layer, implanted with a deep N-type sinker, an isolation region, a base, and an emitter, deposited with metallic interconnect layer, and finally covered with a passivation layer. In this invention, a silicon dioxide deposited on the N-type epitaxial layer is etched by using a combination mask to produce open windows for the deep N-type sinker, the isolation region, the extrinsic base and base. Thereafter, according to the requirements of different processes, the unused windows are covered with photoresists to avoid the alignment errors resulted from the patterning and etching of different masks. Besides, if the bipolar integrated circuit in this invention is required implanted resistor and capacitor, the windows for the implanted resistor and capacitor can be fabricated with the same mask by lithography and etching processes.

Furthermore, when the thickness of the N-type epitaxial layer is less than 10 μm, the isolation and extrinsic layers can be combined in one mask and formed by one masking step, and so that the utalization of the masks for the processes is saved.

### BRIEF DESCRIPTION OF THE DRAWINGS

FIGS. 1 to 31 are the cross-section drawings of the process flow in this invention.

FIGS. 32 to 35 are the cross-section drawings of the process flow with the isolation region and the base.

### DETAILED DESCRIPTION OF THE PREFERRED EMBODIMENTS

The detail contents and illustrations of the technologies of the invention are given below.

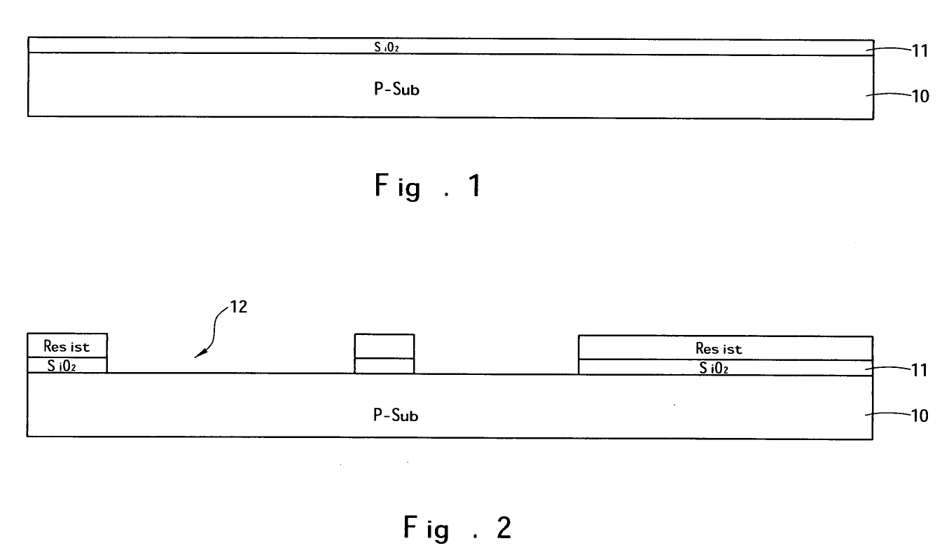

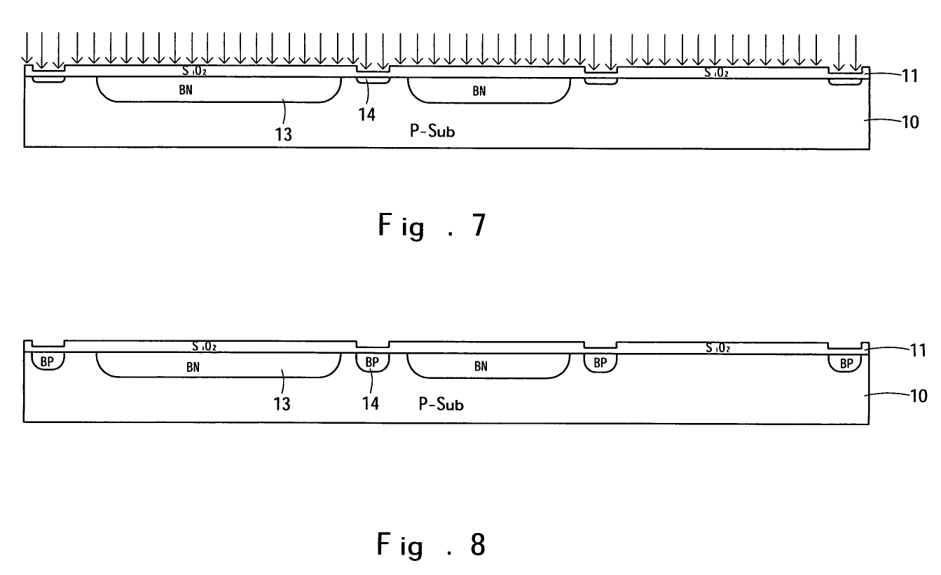

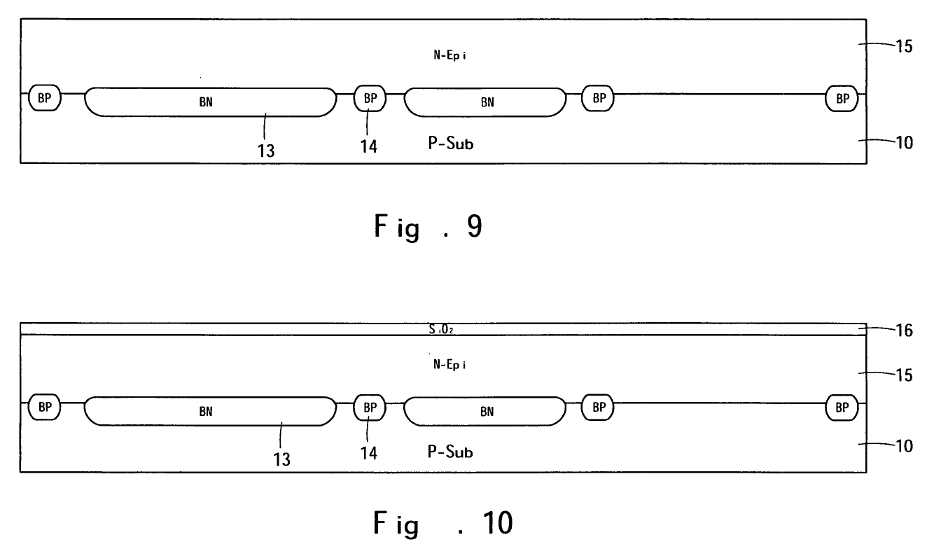

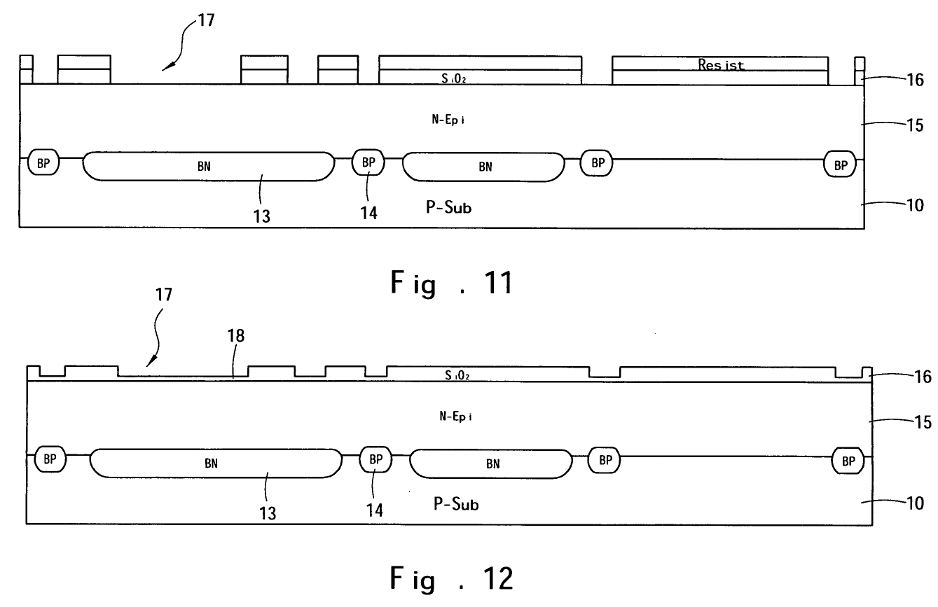

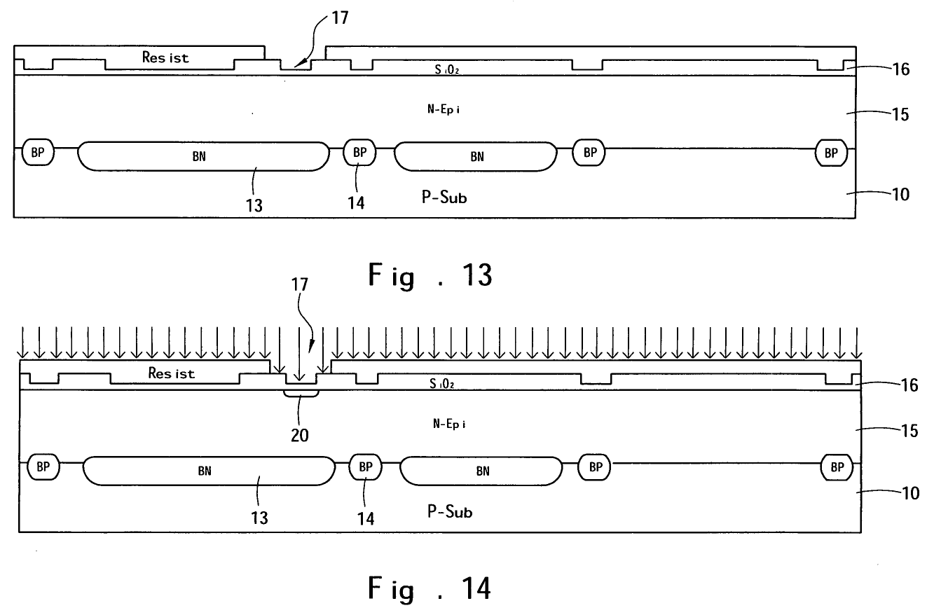

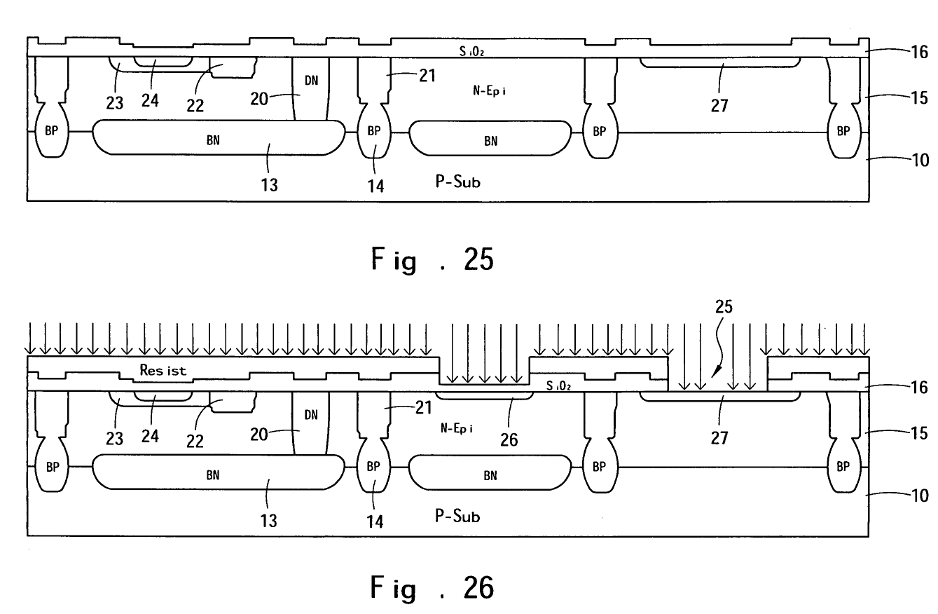

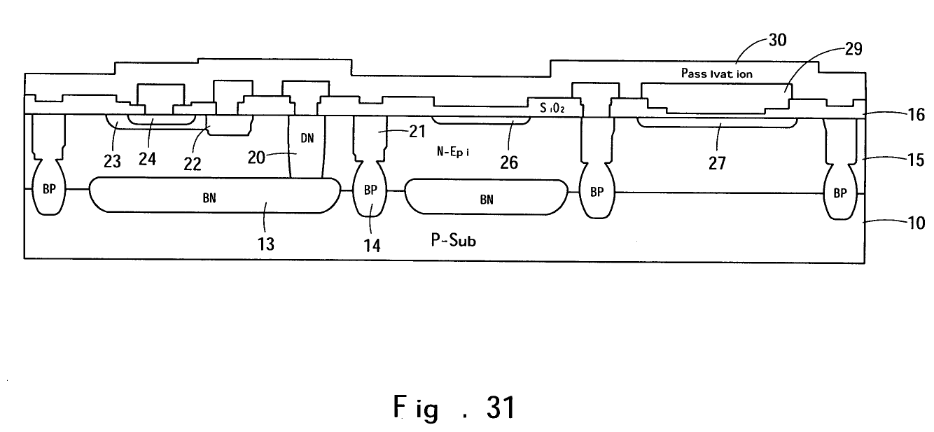

The cross-section drawings of the semi-constructed structures in the process flow of the invention are shown from FIGS. 1 to 31.

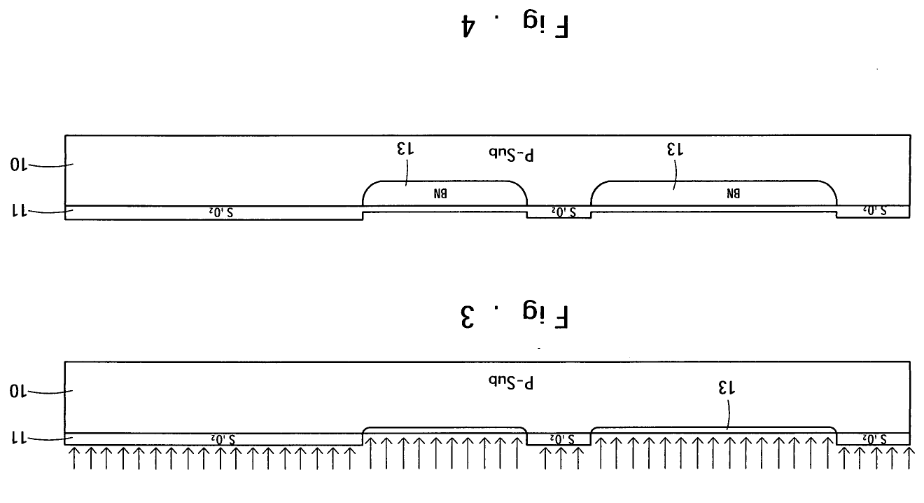

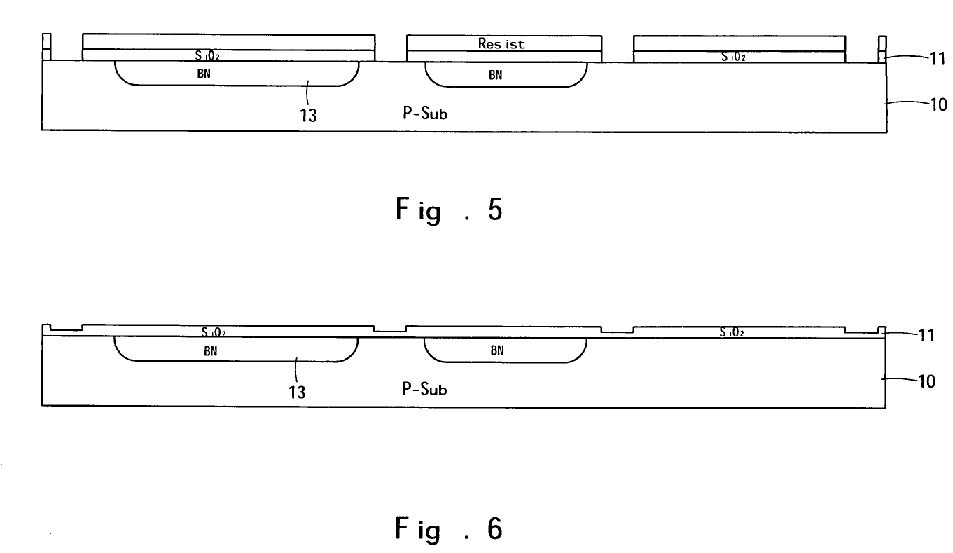

First, as shown in FIG. 1, the process starts with a P-type substrate 10 surfaced with a silicon dioxide layer 11, and which has the open windows 12 by lithography and etching, as shown in FIG. 2. Secondly, as shown in FIGS. 3 and 4, the N-type buried BN region 13 is created by N-type implantation and drive-in. Thirdly, in order to reduce the width of the isolation region, the P-type buried region 14 is implanted and driven-in in advance around the N-type buried region 13 by lithograpgy and etching, as shown from FIGS. 5 to 8.

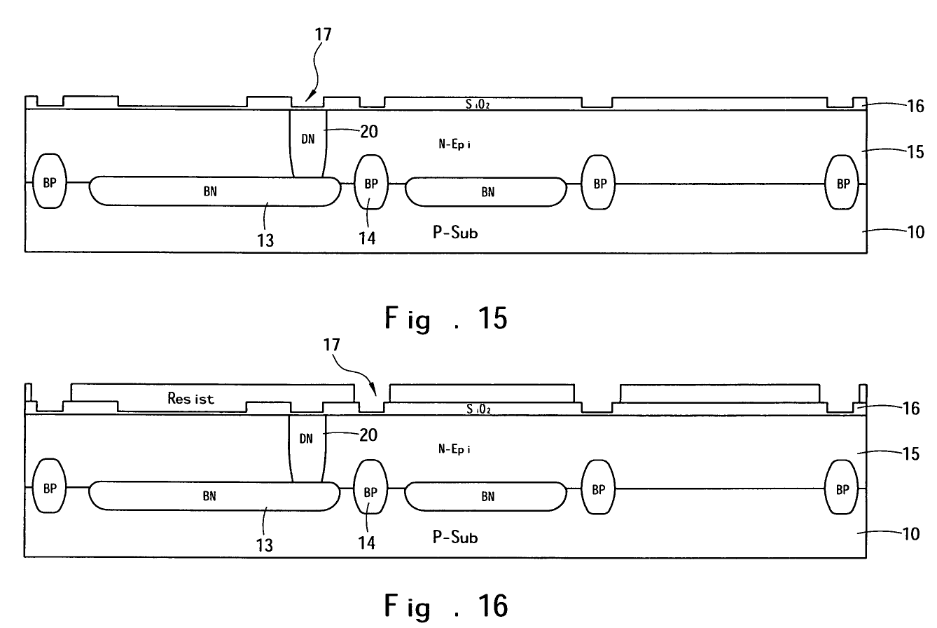

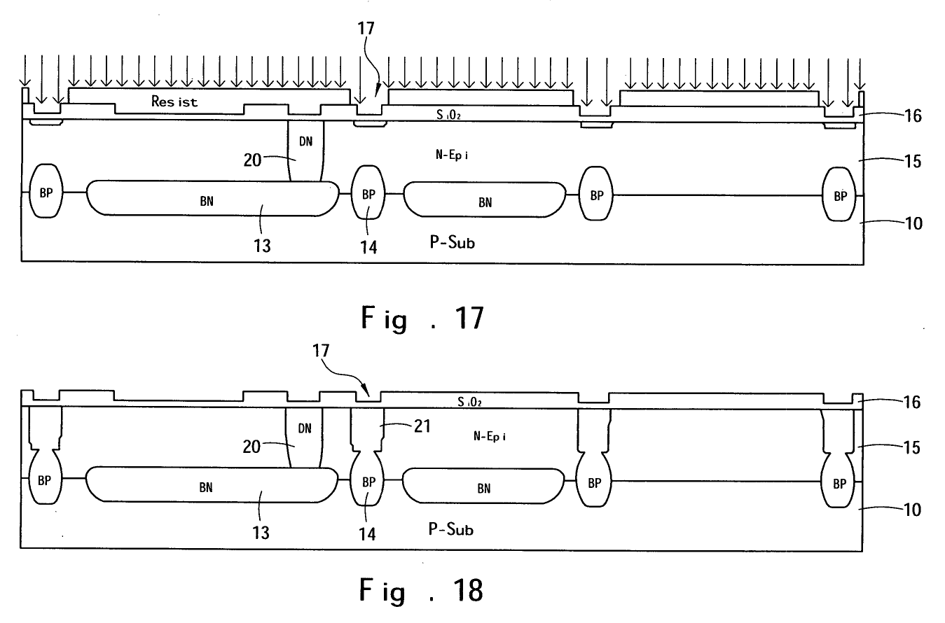

Fourthly, as shown in FIGS. 9 and 10, the silicon dioxide layer 11 is removed, and a N-type epitaxy 15 is deposited and grown with a silicon dioxide layer 16. Thereafter, the open windows 17 for the implantation of the deep N-type sinker 20, the isolation region 21 and the base are created by using the combination mask, photoresist and lithography and etching processes. Next, a screen oxide 18 can be formed through the open windows 17 to increase the scattering of implanting ions. Added to this, the open windows 17 are covered with photoresist except the windows remained for the implantation of deep N-type sinker, as shown in FIG. 13. Then, the deep N-type sinker DN 20 is created by implantation and drive-in, as shown in FIGS. 14 and 15. In the same way, the isolation region 21 is created, as shown from FIGS. 16 to 18.

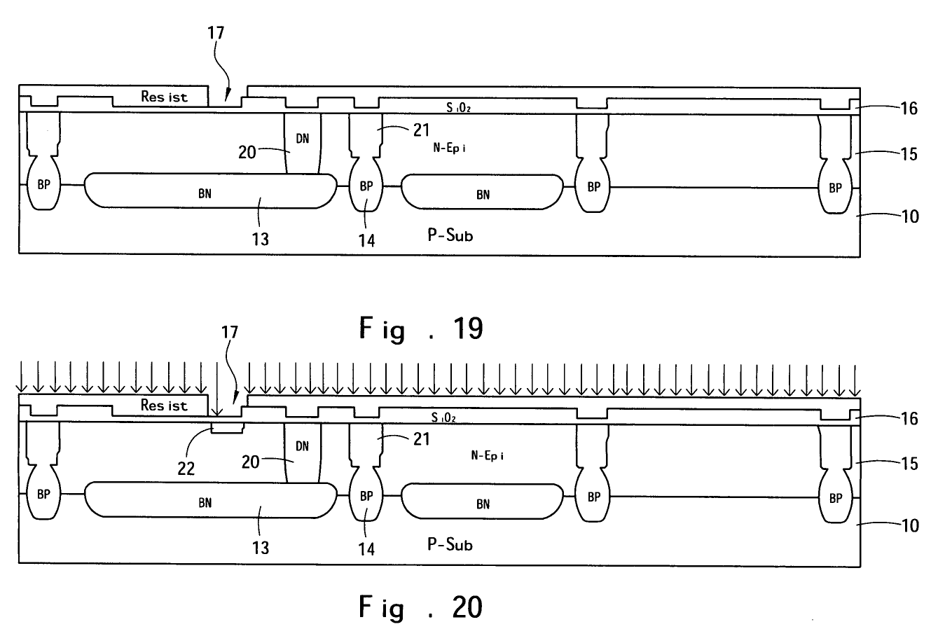

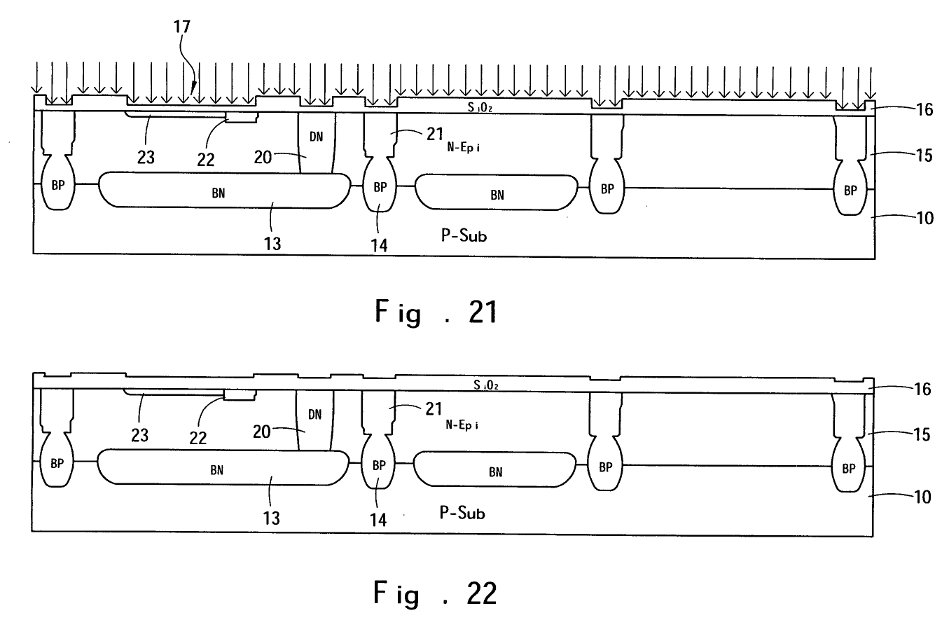

Furthermore, to enhance the performance of the integrated circuit, the extrinsic semicondutor base 22 is implanted and driven-in through the open window 17, as shown in FIGS. 19 and 20. Next, as shown in FIGS. 21 and 22, the photoresist is stripped by plasma etching, and the base 23 is created by implantation and drive-in.

As mentioned above, the implantation and drive-in of the deep N-type sinker 20, the isolation region 21, the extrinsic semicondutor base 22, and the base 23 use the same combination mask, which can avoid the alignment errors due to different masks, and need not to reserve the tolerance for the four process steps, and so that the degree of integration can be improved.

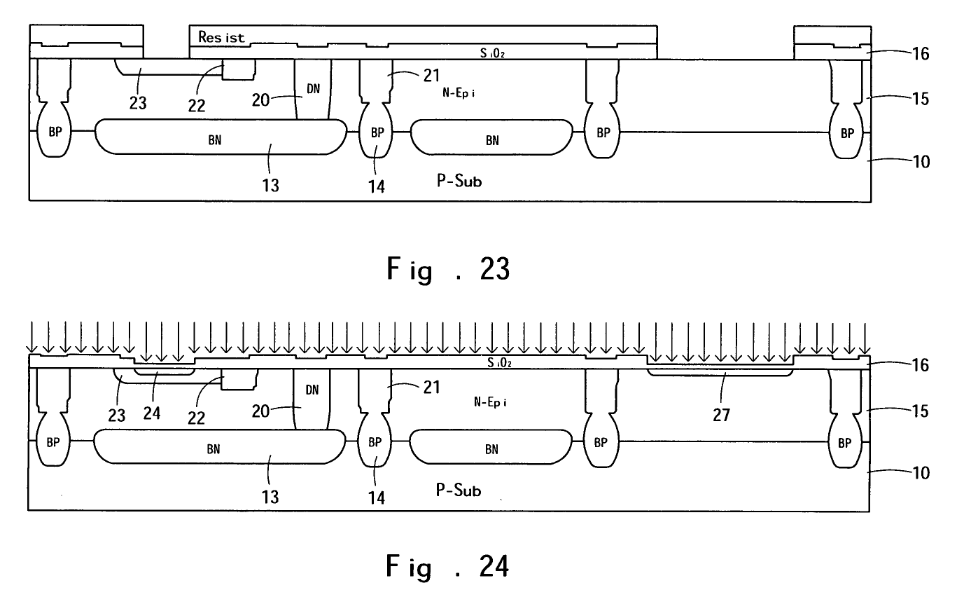

Next, the window for the creation of emitter 24 is made by lithography and etching, and the emitter 24 is implanted and driven-in through the window, as shown from FIGS. 23 to 25.

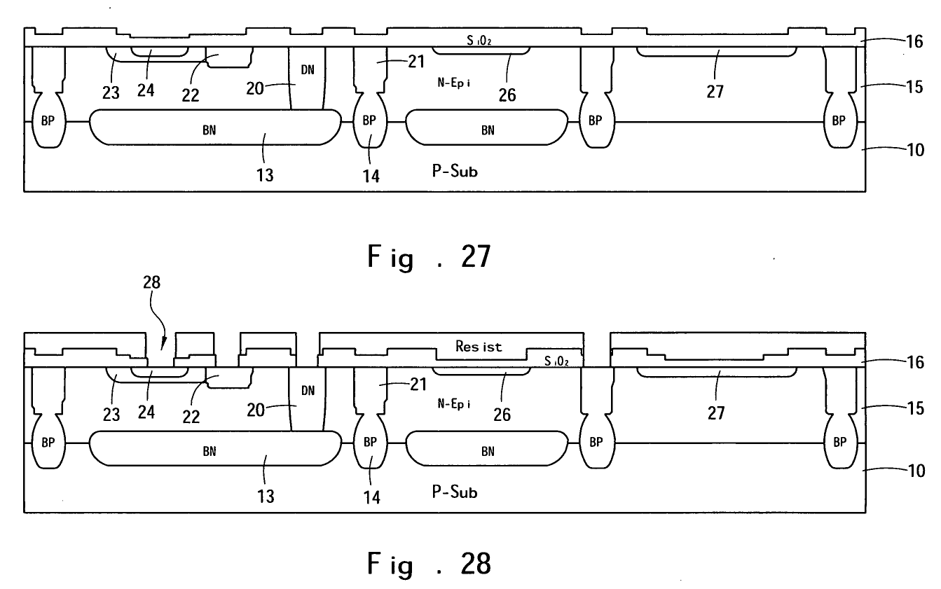

Besides, to extend the design flexibility of circuit in the invention, both the resistance and the capacity can be implanted simultaneously, as shown in FIGS. 26 and 27. The same mask is used to create the resistor 26 and the capacitor 27 through the window 25 fabricated by lithography and etching. The resistor 26 is implanted first, then the dielectric layer (silicon dioxide) for the capacitor 27 is grown by infrared rays annealing.

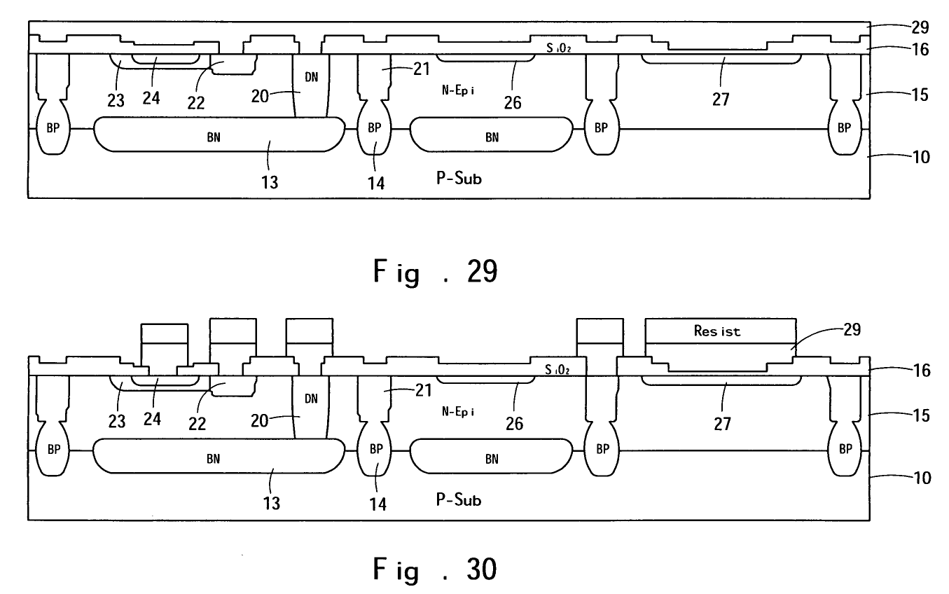

To see the FIG. 28 to FIG. 31, the open window 28 is fabricated through a photoresist, lithography, and etching and then a contact metal 29 is deposited through the window. Except the metal deposited in the window 28, other metals and the photoresist are strpped by lift-off method. Finally the bipolar integrated circuit is completed with a passivation 30.

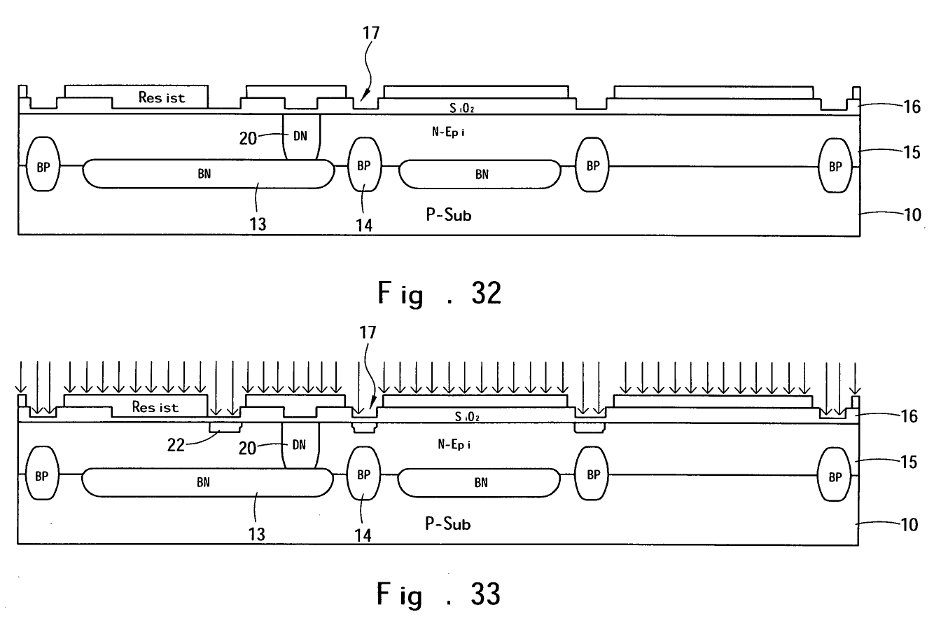

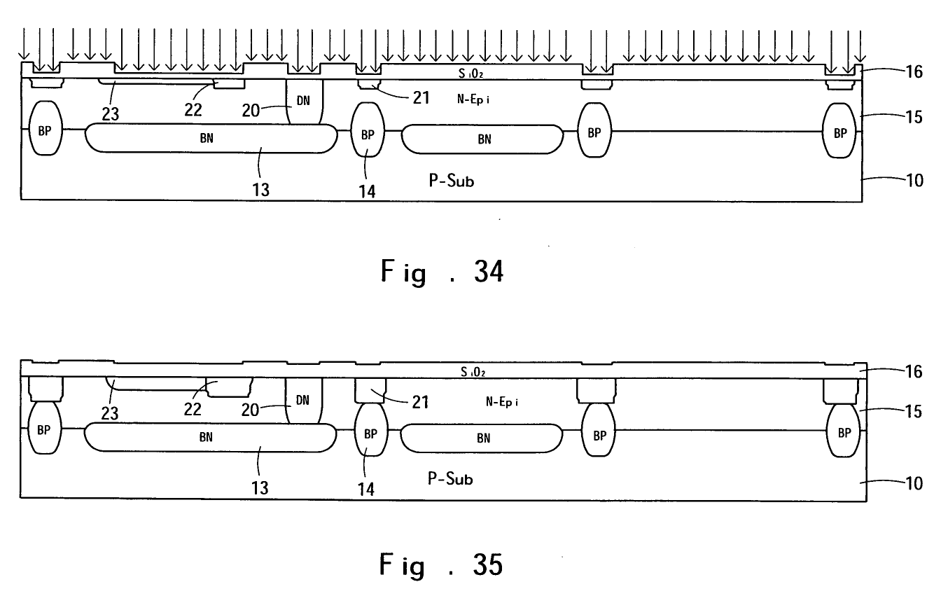

In addition to these, when the thickness of the N-type epitaxial layer 15 is less than 10 μm, referring to FIGS. 32 to 35, the extrinsic semicondutor base 22, the base 23 and the isolation 21 can be implanted at the same time through the windows 17, as shown in FIG. 32, so that the ultalization of mask and the cost of production can be reduced.

It should be concluded, from what has been said above, that a combination mask combined with various patterns of masks using in the different processes (deep N-type sinker, isolation region, extrinsic semicondutor base, and base) is presented in the invention. By using the combination mask, a silicon dioxide layer is etched to produce the open windows required in the previous processes. By this way, the alignment errors from different masks can be avoided, and the degree of integration of the semiconductor processes is enhanced. In addition, the masks for the implantation of the resistor and the capacitor in the invention can be combined in one mask. Furthermore, when the thickness of the N-type epitaxial layer is less than 10 μm, the extrinsic semicondutor base, the base, and the isolation region can be completed at the same time through the windows created with the same mask. Therefore, the degree of integration can be enhanced, and the utalization of mask and the cost of production can be reduced.

What is claimed is:

1. A fabrication method for bipolar integrated circuits and the process sequence of the bipolar integrated circuit starts with a P-type substrate implanted with a N-type buried layer, surfaced with a N-type epitaxial layer, implanted with a deep N-type sinker, an isolation region, a base, and an emitter, deposited with metallic interconnect layer, and finally covered with a passivation layer, characterized by:
a silicon dioxide deposited on the N-type epitaxial layer is etched by using a combination mask to produce open windows for the deep N-type sinker, the isolation region and the base; thereafter, according to the requirements of different processes, the unused windows being covered with photoresists to avoid the alignment errors resulted from the patterning and etching of different masks.

2. The fabrication method for bipolar integrated circuits of claim 1, wherein the P-type buried region is implanted and driven-in in advance around the N-type buried region in the P-type substrate in order to reduce the width of the isolation region.

3. The fabrication method for bipolar integrated circuits of claim 1, wherein an extrinsic semicondutor base can be buried in the integrated circuit, and a silicon dioxide deposited on the N-type epitaxial layer is etched by using a combination mask to produce open windows for the deep N-type sinker, the isolation region, the extrinsic semicondutor base and the base.

4. The fabrication method for bipolar integrated circuits of claim 3, wherein the bipolar integrated circuit required implanted resistor and capacitor, and the windows for the implantated resistor and capacitor can be fabricated with the same mask by lithography and etching processes.

5. The fabrication method for bipolar integrated circuits of claim 4, wherein the P-type buried region is implanted and driven-in in advance around the N-type buried region in the P-type substrate in order to reduce the width of the isolation region.

6. The fabrication method for bipolar integrated circuits of claim 4, wherein the P-type buried region is implanted and driven-in in advance around the N-type buried region in the P-type substrate in order to reduce the width of the isolation region.

7. The fabrication method for bipolar integrated circuits of claim 3, wherein the P-type buried region is implanted and driven-in in advance around the N-type buried region in the P-type substrate in order to reduce the width of the isolation region.

8. The fabrication method for bipolar integrated circuits of claim 3, wherein when the thickness of the N-type epitaxial layer is less than 10 μm, the same mask can be used for the fabrication of the isolation region, the extrinsic semicondutor base and the base.

9. The fabrication method for bipolar integrated circuits of claim 8, wherein the P-type buried region is implanted and driven-in in advance around the N-type buried region in the P-type substrate in order to reduce the width of the isolation region.

10. The fabrication method for bipolar integrated circuits of claim 8, wherein the bipolar integrated circuit required implanted resistor and capacitor, and the windows for the implantated resistor and capacitor can be fabricated with the same mask by lithography and etching processes.

11. The fabrication method for bipolar integrated circuits of claim 10, wherein the P-type buried region is implanted and driven-in in advance around the N-type buried region in the P-type substrate in order to reduce the width of the isolation region.

12. The fabrication method for bipolar integrated circuits of claim 1, wherein when the thickness of the N-type epitaxial layer is less than 10 μm, the same mask can be used for the fabrication of the isolation region and the base.

13. The fabrication method for bipolar integrated circuits of claim 12, wherein the P-type buried region is implanted and driven-in in advance around the N-type buried region in the P-type substrate in order to reduce the width of the isolation region.

14. The fabrication method for bipolar integrated circuits of claim 12, wherein the bipolar integrated circuit required implanted resistor and capacitor, and the windows for the implantated resistor and capacitor can be fabricated with the same mask by lithography and etching processes.

15. The fabrication method for bipolar integrated circuits of claim 14, wherein the P-type buried region is implanted and driven-in in advance around the N-type buried region in the P-type substrate in order to reduce the width of the isolation region.

16. The fabrication method for bipolar integrated circuits of claim 1, wherein the bipolar integrated circuit required implanted resistor and capacitor, and the windows for the implantated resistor and capacitor can be fabricated with the same mask by lithography and etching processes.

17. The fabrication method for bipolar integrated circuits and the process sequence of the bipolar integrated circuit starts with a P-type substrate implanted with a N-type buried layer, surfaced with a N-type epitaxial layer, implanted with a deep N-type sinker, an isolation region, a base, and an emitter, deposited with metallic interconnect layer, and finally covered with a passivation layer, characterized by:
the windows for the implanted resistor and capacitor can be fabricated with the same mask by lithography and etching.

18. The fabrication method for bipolar integrated circuits of claim 17, wherein the P-type buried region is implanted and driven-in in advance around the N-type buried region in the P-type substrate in order to reduce the width of the isolation region.

19. A fabrication method for bipolar integrated circuits and the process sequence of the bipolar integrated circuit starts with a P-type substrate implanted with a N-type buried layer, surfaced with a N-type epitaxial layer, implanted with a deep N-type sinker, an isolation region, a base, and an emitter, deposited with metallic interconnect layer, and finally covered with a passivation layer, characterized by:
when the thickness of the N-type epitaxial layer is less than 10 μm, the same mask can be used for the fabrication of the isolation region, the extrinsic semicondutor base and the base.

20. The fabrication method for bipolar integrated circuits of claim 19, wherein the P-type buried region is implanted and driven-in in advance around the N-type buried region in the P-type substrate in order to reduce the width of the isolation region.
